(19) United States
(12) Patent Application Publication
(10) Pub. No.: US 2021/0248341 A1
(43) Pub. Date: Aug. 12, 2021

(54) PHOTOSENSITIVE DEVICE AND METHOD OF SENSING FINGERPRINT

(71) Applicant: Au Optronics Corporation, Hsinchu (TW)

(72) Inventors: Chia-Po Lin, Hsinchu (TW); Tsai-Sheng Lo, Hsinchu (TW); Chih-Chiang Chen, Hsinchu (TW); Sheng-Ming Huang, Hsinchu (TW); Sheng-Kai Lin, Hsinchu (TW); Ming-Jui Wang, Hsinchu (TW); Chia-Hsin Chung, Hsinchu (TW); Hui-Ku Chang, Hsinchu (TW); Cheng-Chan Wang, Hsinchu (TW); Jen-Kuei Lu, Hsinchu (TW)

(73) Assignee: Au Optronics Corporation, Hsinchu (TW)

(21) Appl. No.: 16/934,028

(22) Filed: Jul. 21, 2020

(30) Foreign Application Priority Data
Feb. 6, 2020 (TW) 109103665

(51) Int. Cl. G06K 9/00; H01L 27/32

(52) U.S. Cl. CPC G06K 9/0004; H01L 27/14678; H01L 27/3234; H01L 27/3244

(57) ABSTRACT

A photosensitive device includes a display panel, a photosensitive element substrate, and a first quarter wave plate. The photosensitive element substrate is located on the back of the display panel. The photosensitive element substrate includes a first substrate, a plurality of first light emitting diodes, a plurality of photosensitive elements, and a first polarizer structure. The first light emitting diodes and the photosensitive elements are located on the first substrate. The first polarizer structure is located on the first light emitting diodes and the photosensitive elements. The first quarter wave plate is located between the first polarizer structure and the display panel.

### CROSS-REFERENCE TO RELATED APPLICATION

This application claims the priority benefit of Taiwan patent application serial no. 109103665, filed on Feb. 6, 2020. The entirety of the above-mentioned patent application is hereby incorporated by reference and made a part of this specification.

### BACKGROUND

### Technical Field

The disclosure relates to a photosensitive device, and in particular, to a photosensitive device and a method of sensing fingerprint.

### Description of Related Art

Currently, fingerprint recognition devices are frequently used in personal electronic products. For instance, electronic products including mobile phones and tablet computers are equipped with the fingerprint recognition devices to ensure that personal privacy of a user is unlikely to be revealed. The existing mobile phones are generally equipped with a photosensitive element for fingerprint recognition. The photosensitive element detects light reflected by a fingerprint. Dermal ridges of the fingerprints reflect light of different intensity, so that different fingerprints may be distinguished by the photosensitive element.

### SUMMARY

The disclosure provides a photosensitive device capable of reducing noise received by a photosensitive element, thereby increasing a success rate of fingerprint recognition.

The disclosure provides a photosensitive device capable of reducing noise received by a photoelectric conversion element, thereby increasing a success rate of fingerprint recognition.

The disclosure provides a method of sensing fingerprint, and the method can reduce noise received by a photoelectric conversion element, thereby increasing a success rate of fingerprint recognition.

At least one embodiment of the disclosure provides a photosensitive device. The photosensitive device includes a display panel, a photosensitive element substrate, and a first quarter wave plate. The photosensitive element substrate is located on a back of the display panel. The photosensitive element substrate includes a first substrate, a plurality of first light emitting diodes, a plurality of photosensitive elements, and a first polarizer structure. The first light emitting diodes and the photosensitive elements are located on the first substrate. The first polarizer structure is located on the first light emitting diodes and the photosensitive elements. The first quarter wave plate is located between the first polarizer structure and the display panel.

At least one embodiment of the disclosure provides a photosensitive device. The photosensitive device includes a display panel, a photosensitive element substrate, and a first quarter wave plate. The photosensitive element substrate is located on a back of the display panel. The photosensitive element substrate includes a first substrate, a plurality of photoelectric conversion elements, and a first polarizer structure. The photoelectric conversion elements are located on the first substrate. The first polarizer structure is located on the photoelectric conversion elements. The first quarter wave plate is located between the first polarizer structure and the display panel.

At least one embodiment of the disclosure provides a fingerprint sensing method, including following steps. A photosensitive device including a display panel, a photosensitive element substrate, and a first quarter wave plate is provided. The photosensitive element substrate is located on a back of the display panel. The photosensitive element substrate includes a first substrate, a plurality of photoelectric conversion elements, and a first polarizer structure. The photoelectric conversion elements are located on the first substrate. The first polarizer structure is located on the photoelectric conversion elements. The first quarter wave plate is located between the first polarizer structure and the display panel. A voltage is applied to one portion of the photoelectric conversion elements, so that the one portion of the photoelectric conversion elements emit light.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a photosensitive device according to an embodiment of the disclosure.

FIG. 2 is a schematic cross-sectional view of a photosensitive device according to an embodiment of the disclosure.

FIG. 3 is a schematic cross-sectional view of a photosensitive device according to an embodiment of the disclosure.

FIG. 4 is a schematic cross-sectional view of a photosensitive device according to an embodiment of the disclosure.

FIG. 5 is a schematic cross-sectional view of a photosensitive device according to an embodiment of the disclosure.

### DESCRIPTION OF THE EMBODIMENTS

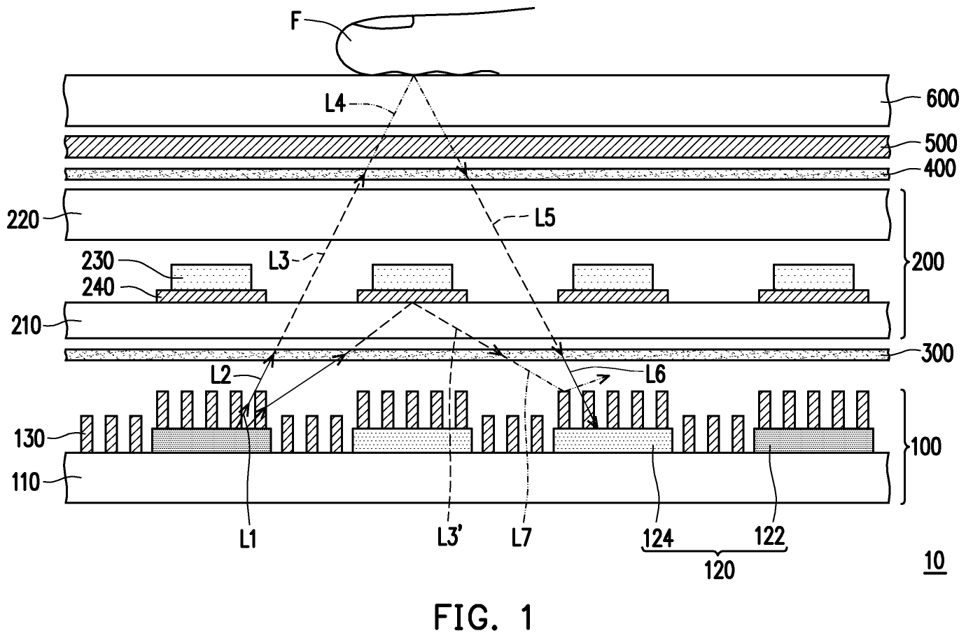

FIG. 1 is a schematic cross-sectional view of a photosensitive device according to an embodiment of the disclosure.

With reference to FIG. 1, a photosensitive device 10 includes a photosensitive element substrate 100, a display panel 200, and a first quarter wave plate 300.

The photosensitive element substrate 100 is located on the back of the display panel 200. The photosensitive element substrate 100 includes a first substrate 110, a plurality of photoelectric conversion elements 120, and a first polarizer structure 130.

The photoelectric conversion elements 120 are located on the first substrate 110. The photoelectric conversion element 120 includes a first light emitting diode 122 and a photosensitive element 124. The first light emitting diode 122 includes an organic light emitting diode, an inorganic light emitting diode, or other self-light emitting elements. The photosensitive element 124 includes a pin-type photosensitive element, an avalanche photosensitive element, a pn-type photosensitive element, an emission key photosensitive element, or other photosensitive elements. In some embodiments, the first light emitting diode 122 and the photosensitive element 124 include the same structure. For example, both the first light emitting diode 122 and the photosensitive element 124 include a P-type semiconductor and an N-type semiconductor. When a forward bias voltage is applied to the photoelectric conversion element 120, electrons and electron holes are combined in a depletion region between the P-type semiconductor and the N-type semiconductor, and light is emitted. When a reverse bias voltage is applied to the photoelectric conversion element 120 and light is irradiated to the photoelectric conversion element 120, an electron hole pair is generated in the depletion region between the P-type semiconductor and the N-type semiconductor, and a current is generated. In other embodiments, the first light emitting diode 122 and the photosensitive element 124 include different structures.

The first polarizer structure 130 is located on the photoelectric conversion element 120 and between the photoelectric conversion element 120 and the display panel 200. In the present embodiment, the first polarizer structure 130 is located on the first light emitting diode 122 and the photosensitive element 124. The first polarizer structure 130 is a metal grid line polarization structure. The first polarizer structure 130 may be formed through nanoimprint lithography (NIL). The metal grid line polarization structure is located on the first light emitting diode 122 and the photosensitive element 124. The metal grid line polarization structure is made of, for example, gold, aluminum, copper, nickel, etc.

The display panel 200 includes a third substrate 210, a fourth substrate 220 opposite to the third substrate 210, a plurality of second light emitting diodes 230, and a reflecting layer 240. The second light emitting diode 230 and the reflecting layer 240 are located on the third substrate 210. The second light emitting diode 230 includes an organic light emitting diode, an inorganic light emitting diode, or other self-light emitting elements. The second light emitting diode 230 and the first light emitting diode 122 may have the same size or different sizes, and there may be the same number or different numbers of second light emitting diodes 230 and first light emitting diodes 122. The reflecting layer 240 is located between the second light emitting diode 230 and the third substrate 210. The reflecting layer 240 includes, for example, metal wires, metal electrodes, or other structures that can reflect light. In some embodiments, there is an optical glue between the third substrate 210 and the fourth substrate 220. The optical glue may be used for protecting the second light emitting diode 230.

In some embodiments, the first light emitting diode 122 is an infrared light emitting diode, and the second light emitting diode 230 is a visible light emitting diode, thereby avoiding interference between light emitted by the first light emitting diode 122 and light emitted by the second light emitting diode 230.

The first quarter wave plate 300 is located between the first polarizer structure 130 and the display panel 200. The first quarter wave plate 300 is formed on the photosensitive element substrate 100 or the display panel 200. An included angle exists between a fast axis of the first quarter wave plate 300 and a transmission axis of the first polarizer structure 130. For example, the included angle between the fast axis of the first quarter wave plate 300 and the transmission axis of the first polarizer structure 130 is +45 degrees.

In the present embodiment, the photosensitive device 10 further includes a second quarter wave plate 400, a second polarizer structure 500, and a cover plate 600.

The second quarter wave plate 400 is located on the display panel 200. The first quarter wave plate 300 and the second quarter wave plate 400 are respectively located on two opposite sides of display panel 200. In some embodiments, the first quarter wave plate 300 is located on the third substrate 210 of the display panel 200, and the second quarter wave plate 400 is located on the fourth substrate 220 of the display panel 200.

The second polarizer structure 500 is located on the second quarter wave plate 400, and the second quarter wave plate 400 is located between the second polarizer structure 500 and the display panel 200. In some embodiments, the second polarizer structure 500 may include a polyvinyl alcohol (PVA) polarization film, an advanced polarization conversion film (APCF), a reflective polarization brightness enhancement film (dual brightness enhancement film, DBEF), or other polarizer structures. In some embodiments, the second polarizer structure 500 may further include a metal grid line polarization structure.

In the present embodiment, an included angle exists between a fast axis of the second quarter wave plate 400 and the fast axis of the transmission axis of the first polarizer structure 130. For example, the included angle between the fast axis of the second quarter wave plate 400 and the transmission axis of the first polarizer structure 130 is −45 degrees, and the transmission axis of the first polarizer structure 130 and a transmission axis of the second polarizer structure 500 are parallel to each other. In other embodiments, the included angle between the fast axis of the second quarter wave plate 400 and the transmission axis of the first polarizer structure 130 is +45 degrees, and the transmission axis of the first polarizer structure 130 and the transmission axis of the second polarizer structure 500 are perpendicular or parallel to each other.

The cover plate 600 is located on the second polarizer structure 500. The second quarter wave plate 400 and the second polarizer structure 500 are formed on the display panel 200 or on the cover plate 600.

In the present embodiment, a voltage is applied to some of the photoelectric conversion elements 120 (the first light emitting diode 122) to cause some of the photoelectric conversion elements 120 (the first light emitting diode 122) to emit light L1. Light L1 passes through the first polarizer structure 130 and is converted into first polarized light L2 by the first polarizer structure 130. A polarization direction of the first polarized light L2 is parallel to the transmission axis of the first polarizer structure 130.

The first polarized light L2 passes through the first quarter wave plate 300 and is converted into first circular polarized light L3 by the first quarter wave plate 300. In the present embodiment, a part of the first circular polarized light L3 passes through the display panel 200 and arrives at the second quarter wave plate 400.

The first circular polarized light L3 passes through the second quarter wave plate 400 and is converted into second polarized light L4 by the second quarter wave plate 400. A polarization direction of the second polarized light L4 is parallel to the transmission axis of the second polarizer structure 500.

The second polarized light L4 passes through the second polarizer structure 500 and is then reflected by a finger F, and then passes through the second polarizer structure 500 again. The second polarized light L4 passes through the second quarter wave plate 400 and is converted into second circular polarized light L5 by the second quarter wave plate 400.

The second circular polarized light L5 passes through the first quarter wave plate 300 and is converted into third polarized light L6 by the first quarter wave plate 300. A polarization direction of the third polarized light L6 is parallel to the transmission axis of the first polarizer structure 130.

The third polarized light L6 passes through the first polarizer structure 130 and is received by others of the photoelectric conversion elements 120 (the photosensitive element 124). The others of the photoelectric conversion elements 120 (the photosensitive element 124) generate a current signal corresponding to the light reflected by the finger, thereby achieving fingerprint recognition.

In the present embodiment, partial first circular polarized light L3′ is reflected by the reflecting layer 240 below the second light emitting diode 230 and returns to the first quarter wave plate 300. The first circular polarized light L3′ passes through the first quarter wave plate 300 and is converted into fourth polarized light L7 by the first quarter wave plate 300. A polarization direction of the fourth polarized light L7 is perpendicular to the transmission axis of the first polarizer structure 130. Since the polarization direction of the fourth polarized light L7 is perpendicular to the transmission axis of the first polarizer structure 130, the fourth polarized light L7 cannot penetrate the first polarizer structure 130. Therefore, the others of the photoelectric conversion elements 120 (the photosensitive element 124) generate no noise current signal corresponding to the fourth polarized light L7.

Based on the above, since the first quarter wave plate 300 is located between the first polarizer structure 130 and the display panel 200, noise received by the photoelectric conversion element 120 (the photosensitive element 124) from the reflecting layer 240 may be reduced, thereby increasing a success rate of fingerprint recognition.

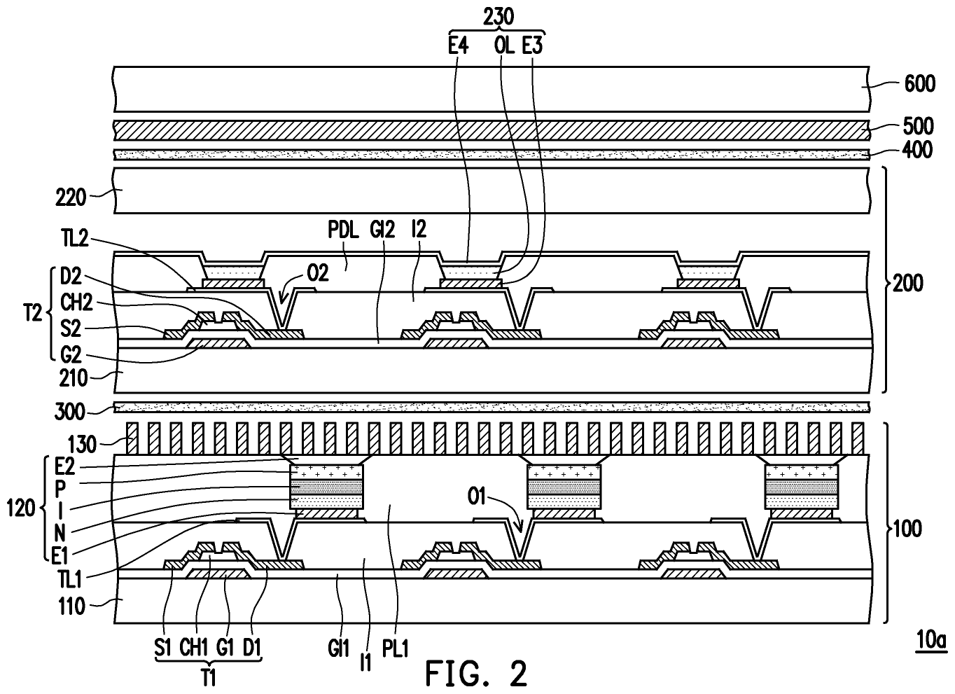

FIG. 2 is a schematic cross-sectional view of a photosensitive device according to an embodiment of the disclosure. It should be mentioned that reference numbers and some content in the embodiment of FIG. 2 are the same as those in the embodiment in FIG. 1, the same or similar reference numbers serve to represent the same or similar elements, and descriptions about the same technical content are omitted. For the descriptions of the omitted part, reference may be made to the above embodiments, and the descriptions thereof are omitted herein.

With reference to FIG. 2, in the present embodiment, the photoelectric conversion element 120 includes a pin-type diode.

As shown in FIG. 2, the photosensitive element substrate 100 includes a plurality of switching elements T1. Each of the switching elements T1 includes a gate G1, a channel layer CH1, a source S1, and a drain D1. The gate G1 is located on the first substrate 110. The channel layer CH1 overlaps the gate G1, and there is a gate insulating layer GI1 between the channel layer and the gate G1. The source S1 and the drain D1 are located on the channel layer CH1 and are connected to the channel layer CH1.

Although the switching element T1 is a bottom gate thin film transistor in the present embodiment, for example, the disclosure is not limited thereto. According to other embodiments, the switching element T1 may also be a top gate thin film transistor or other types of thin film transistors.

The insulating layer I1 covers the switching element T1. The insulating layer I1 has a plurality of openings O1. The source S1 or the drain D1 of the switching element T1 is exposed from the opening O1. A plurality of transfer electrodes TL1 fill the opening O1 and are electrically connected to the source S1 or the drain D1 of the switching element T1.

The photoelectric conversion element 120 is located on the insulating layer I1. The photoelectric conversion element 120 includes a layer P (P), a layer I (I), a layer N (N), a first electrode E1, and a second electrode E2. The layer P (P) and the layer N (N) are a P-type semiconductor layers and an N-type semiconductor layers respectively. The layer I (I) is located between the layer P (P) and the layer N (N), and doping concentration of the layer I (I) is lower than doping concentration of the layer P (P) and the layer N (N). The first electrode E1 connects the layer N (N) to the transfer electrode TL1. The second electrode E2 is connected to the layer P (P). In the present embodiment, the second electrode E2 includes a transparent conductive material.

The planarization layer PL1 is located on the first substrate 110. In the present embodiment, the planarization layer PL1 covers the insulating layer I1, and the photoelectric conversion element 120 is embedded in the planarization layer PL1. In other words, the first light emitting diode and the photosensitive element are embedded in the planarization layer PL1.

In the present embodiment, the switching element T1 is configured to control a bias voltage to be applied to the photoelectric conversion element 120, to determine whether the photoelectric conversion element 120 is configured to emit light or receive light. For example, when a forward bias voltage is applied to the photoelectric conversion element 120, the photoelectric conversion element 120 may be used as a light emitting diode. When a reverse bias voltage is applied to the photoelectric conversion element 120, the photoelectric conversion element 120 may be used as a photosensitive element. In this way, a ratio of the light emitting diode to the photosensitive element may be adjusted according to light intensity existing during operating of the photosensitive element substrate 100, thereby increasing the success rate of fingerprint recognition.

The first polarizer structure 130 is located on the planarization layer PL1. In the present embodiment, the first polarizer structure 130 is located on the planarization layer PL1 and the photoelectric conversion element 120. In some embodiments, there are other insulating layers (not shown) between the photoelectric conversion element 120 and the first polarizer structure 130, but the disclosure is not limited thereto. The first polarizer structure 130 may be better formed through NIL with the disposed planarization layer PL1.

The display panel 200 includes a plurality of switching elements T2. Each of the switching elements T2 includes a gate G2, a channel layer CH2, a source S2, and a drain D2. The gate G2 is located on the third substrate 210. The channel layer CH2 overlaps the gate G2, and there is a gate insulating layer GI2 between the channel layer and the gate G2. The source S2 and the drain D2 are located on the channel layer CH2 and are connected to the channel layer CH2.

Although the switching element T2 is a bottom gate thin film transistor in the present embodiment, for example, the disclosure is not limited thereto. According to other embodiments, the switching element T2 may also be a top gate thin film transistor or other types of thin film transistors.

The insulating layer 12 covers the switching element T2. The insulating layer 12 has a plurality of openings O2. The drain D2 of the switching element T2 is exposed from the opening O2. A plurality of transfer electrodes TL2 fill the opening O2 and are electrically connected to the drain D2 of the switching element T2.

The second light emitting diode 230 is located on the insulating layer 12. In the present embodiment, the second light emitting diode 230 is an organic light emitting diode, and each of the second light emitting diodes 230 includes a third electrode E3, a fourth electrode E4, and an organic light emitting layer OL. The organic light emitting layer OL is located between the third electrode E3 and the fourth electrode E4.

In the present embodiment, a pixel definition layer PDL is located on the insulating layer 12 and has an opening overlapping the third electrode E3. The organic light emitting layer OL is located in the opening of the pixel definition layer PDL, and the fourth electrode E4 is located on the organic light emitting layer OL and the pixel definition layer PDL. In the present embodiment, the third electrode E3 of each of the second light emitting diodes 230 is electrically connected to a corresponding switching element T2 through the transfer electrode TL2. In the present embodiment, the fourth electrodes E4 of the second light emitting diodes 230 are electrically connected to each other.

Based on the above, since the first quarter wave plate 300 is located between the first polarizer structure 130 and the display panel 200, noise received by the photoelectric conversion element 120 (the photosensitive element) may be reduced, thereby increasing the success rate of fingerprint recognition.

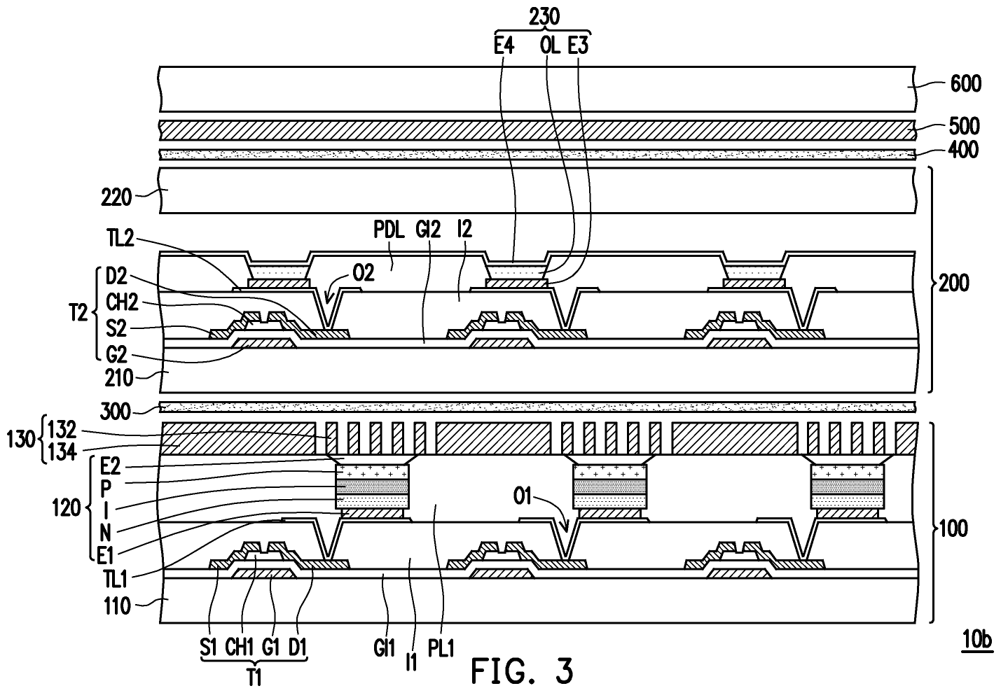

FIG. 3 is a schematic cross-sectional view of a photosensitive device according to an embodiment of the disclosure. It should be mentioned that reference numbers and some content in the embodiment of FIG. 3 are the same as those in the embodiment in FIG. 2, the same or similar reference numbers serve to represent the same or similar elements, and descriptions about the same technical content are omitted. For the descriptions of the omitted part, reference may be made to the above embodiments, and the descriptions thereof are omitted herein.

A main difference between a photosensitive device 10b in FIG. 3 and the photosensitive device 10a in FIG. 2 lies in that the photosensitive device 10b further includes a reflecting layer 134.

With reference to FIG. 3, in the present embodiment, the first polarizer structure 130 includes a plurality of metal grid line polarization structures 132 and the reflecting layer 134. The metal grid line polarization structure 132 is located on the photoelectric conversion element 120 (the first light emitting diode and the photosensitive element). For example, the metal grid line polarization structure 132 is located on only a light emitting surface or a light receiving surface of the photoelectric conversion element 120. The reflecting layer 134 is located between the metal grid line polarization structures 132. For example, a part of the first polarizer structure 130 overlapping the photoelectric conversion element 120 is the metal grid line polarization structure 132, and a part of the first polarizer structure 130 not overlapping the photoelectric conversion element 120 is the reflecting layer 134.

In the present embodiment, the metal grid line polarization structure 132 and the reflecting layer 134 include the same material and are formed by performing the same patterning process, but the disclosure is not limited thereto. In other embodiments, the metal grid line polarization structure 132 and the reflecting layer 134 include different materials.

Based on the above, the reflecting layer 134 may reflect light reflected by the display panel 200, thereby increasing a probability that light penetrates the display panel 200.

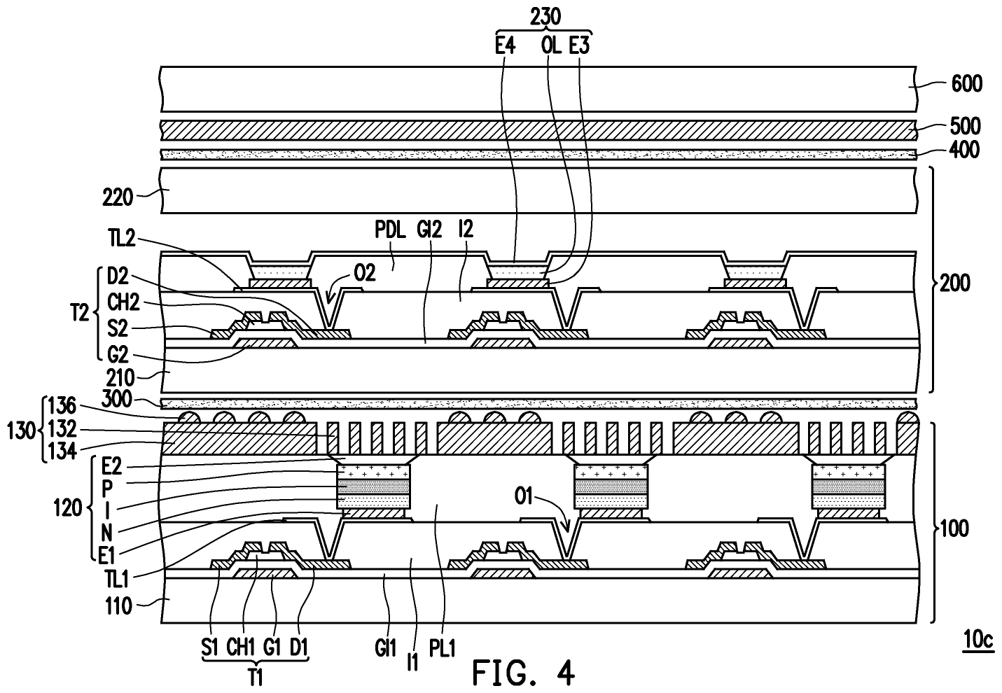

FIG. 4 is a schematic cross-sectional view of a photosensitive device according to an embodiment of the disclosure. It should be mentioned that reference numbers and some content in the embodiment of FIG. 4 are the same as those in the embodiment in FIG. 3, the same or similar reference numbers serve to represent the same or similar elements, and descriptions about the same technical content are omitted. For the descriptions of the omitted part, reference may be made to the above embodiments, and the descriptions thereof are omitted herein.

A main difference between a photosensitive device 10c in FIG. 4 and the photosensitive device 10b in FIG. 3 lies in that the photosensitive device 10c further includes a reflecting structure 136.

With reference to FIG. 4, in the present embodiment, the first polarizer structure 130 includes a metal grid line polarization structure 132, a reflecting layer 134, and a plurality of reflecting structures 136. The reflecting structure 136 is located on a surface of the reflecting layer 134.

In the present embodiment, the metal grid line polarization structure 132, the reflecting layer 134, and the reflecting structure 136 include the same material. In some embodiments, the reflecting structure 136 is formed on the surface of the reflecting layer 134 by using an etching process.

Based on the above, the reflecting structure 136 may increase light scattering and light reflection at a large angle, thereby increasing the probability that light penetrates the display panel 200.

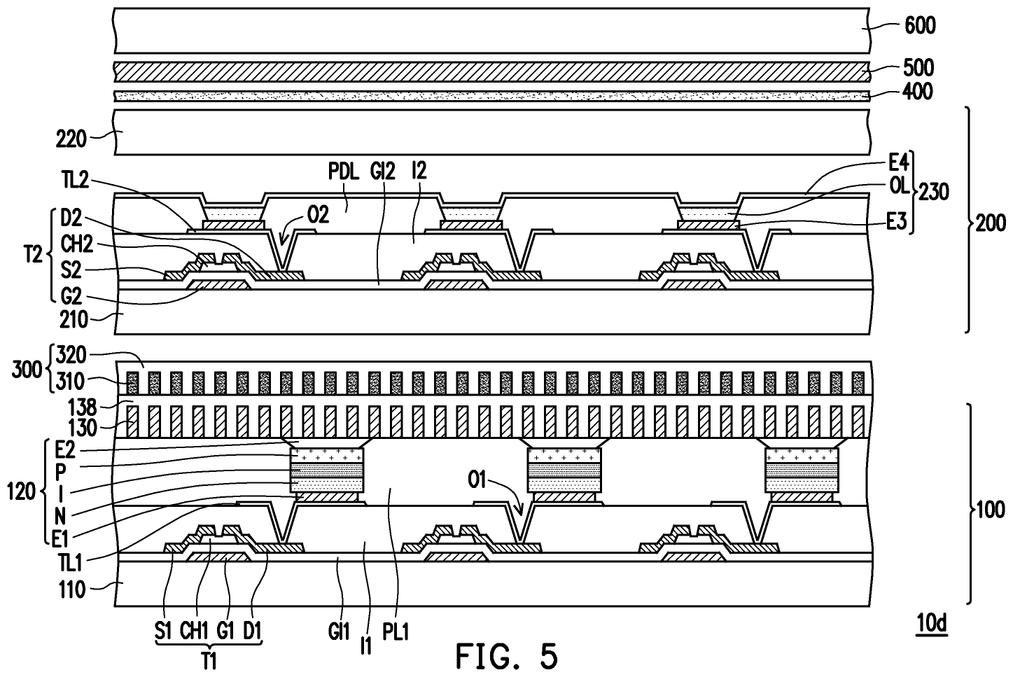

FIG. 5 is a schematic cross-sectional view of a photosensitive device according to an embodiment of the disclosure. It should be mentioned that reference numbers and some content in the embodiment of FIG. 5 are the same as those in the embodiment in FIG. 2, the same or similar reference numbers serve to represent the same or similar elements, and descriptions about the same technical content are omitted. For the descriptions of the omitted part, reference may be made to the above embodiments, and the descriptions thereof are omitted herein.

A main difference between a photosensitive device 10d in FIG. 5 and the photosensitive device 10a in FIG. 2 lies in that a first quarter wave plate 300 of the photosensitive device 10d is a grating retarder.

With reference to FIG. 5, a passivation layer 138 covers the first polarizer structure 130. The first quarter wave plate 300 includes a grating 310. The grating 310 is located on the passivation layer 138. The grating 310 includes, for example, a transparent insulating material, and may also be formed through NIL. The insulating layer 320 covers the grating 310. Since the first quarter wave plate 300 is a grating retarder, the photosensitive device 10d may be thinner, and flexibility of the photosensitive device 10d may be improved.

Although the first quarter wave plate 300 is a grating retarder in the present embodiment, the disclosure is not limited thereto. In other embodiments, the first quarter wave plate 300 is a polymer wave plate, a liquid crystal wave plate, a multi-layer film stacked wave plate, or other forms of wave plates.

In some embodiments, the second quarter wave plate 400 may also be a grating retarder, but the disclosure is not limited thereto. In other embodiments, the second quarter wave plate 400 is a polymer wave plate, a liquid crystal wave plate, a multi-layer film stacked wave plate, or other forms of wave plates.

Based on the above, the first quarter wave plate is located between the first polarizer structure and the display panel, so that noise received by the photoelectric conversion element may be reduced, thereby increasing the success rate of fingerprint recognition.

It will be apparent to those skilled in the art that various modifications and variations can be made to the disclosed embodiment without departing from the scope or spirit of the disclosure. In view of the foregoing, it is intended that the disclosure covers modifications and variations provided that they fall within the scope of the following claims and their equivalents.

What is claimed is:

1. A photosensitive device, comprising:
a display panel;
a photosensitive element substrate, located on a back of the display panel and comprising:
a first substrate;
a plurality of first light emitting diodes, located on the first substrate;
a plurality of photosensitive elements, located on the first substrate; and
a first polarizer structure, located on the first light emitting diodes and the photosensitive elements; and
a first quarter wave plate, located between the first polarizer structure and the display panel.

2. The photosensitive device according to claim 1, wherein the display panel comprises:
a third substrate and a fourth substrate opposite to the third substrate; and
a plurality of second light emitting diodes, located on the third substrate.

3. The photosensitive device according to claim 1, further comprising:
a second quarter wave plate, located on the display panel; and
a second polarizer structure, wherein the second quarter wave plate is located between the second polarizer structure and the display panel.

4. The photosensitive device according to claim 3, wherein the first quarter wave plate and the second quarter wave plate are respectively located on two opposite sides of the display panel.

5. The photosensitive device according to claim 3, wherein a transmission axis of the first polarizer structure and a transmission axis of the second polarizer structure are parallel or perpendicular to each other.

6. The photosensitive device according to claim 3, wherein an included angle exists between a fast axis of the first quarter wave plate and a fast axis of the second quarter wave plate.

7. The photosensitive device according to claim 1, wherein an included angle exists between a fast axis of the first quarter wave plate and a transmission axis of the first polarizer structure.

8. The photosensitive device according to claim 1, wherein the first polarizer structure comprises:
a plurality of metal grid line polarization structures, located on the first light emitting diodes and the photosensitive elements; and
a reflecting layer, located between the metal grid line polarization structures.

9. The photosensitive device according to claim 8, wherein the first polarizer structure comprises:
a plurality of reflecting structures, located on a surface of the reflecting layer.

10. The photosensitive device according to claim 1, wherein the photosensitive element substrate comprises:
a planarization layer, located on the first substrate, wherein the first light emitting diodes and the photosensitive elements are embedded in the planarization layer, and the first polarizer structure is located on the planarization layer.

11. A photosensitive device, comprising:
a display panel;
a photosensitive element substrate, located on a back of the display panel and comprising:
a first substrate;
a plurality of photoelectric conversion elements, located on the first substrate; and
a first polarizer structure, located on the photoelectric conversion elements; and
a first quarter wave plate, located between the first polarizer structure and the display panel.

12. A fingerprint sensing method, comprising:
providing a photosensitive device, the photosensitive device comprising:
a display panel, comprising:
a photosensitive element substrate, located on a back of the display panel and comprising: a first substrate;
a plurality of photoelectric conversion elements, located on the first substrate; and
a first polarizer structure, located on the photoelectric conversion elements; and
a first quarter wave plate, located between the first polarizer structure and the display panel; and
applying a voltage to one portion of the photoelectric conversion elements, so that the one portion of the photoelectric conversion elements emit light.

13. The fingerprint sensing method according to claim 12, wherein the display panel comprises:
a third substrate and a fourth substrate opposite to the third substrate; and
a plurality of light emitting diodes, located on the third substrate, wherein the photosensitive device further comprises:
a second polarizer structure, located on the fourth substrate; and
a second quarter wave plate, located between the second polarizer structure and the light emitting diodes.

14. The fingerprint sensing method according to claim 13, wherein
light emitted by the one portion of the photoelectric conversion elements passes through the first polarizer structure and is converted into first polarized light,
the first polarized light passes through the first quarter wave plate and is converted into first circular polarized light,
the first circular polarized light passes through the second quarter wave plate and is converted into second polarized light,
the second polarized light passes through the second polarizer structure, is then reflected by a finger, and passes through the second polarizer structure again,
the second polarized light passes through the second quarter wave plate and is converted into second circular polarized light,
the second circular polarized light passes through the first quarter wave plate and is converted into third polarized light, and
the third polarized light passes through the first polarizer structure and is received by the other portion of the photoelectric conversion elements.
